(19) United States
(12) Patent Application Publication
(10) Pub. No.: US 2026/0362727 A1
(43) Pub. Date: Nov. 12, 2026

(54) SEMICONDUCTOR DEVICE AND METHOD FOR FORMING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Jin-Bin YANG, Taichung City (TW); Liang Chun CHEN, Hualien County (TW); I-Chih NI, New Taipei City (TW); Chih-I WU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 19/294,090

(22) Filed: Aug. 7, 2025

Related U.S. Application Data
(60) Provisional application No. 63/801,366, filed on May 7, 2025.

(51) Int. Cl. H10D 30/01; H10D 30/47

(52) U.S. Cl. CPC H10D 30/017; H10D 30/481

(57) ABSTRACT

A method includes forming a 2-D material channel layer over a substrate, wherein the 2-D material channel layer is made of transition metal dichalcogenide (TMD); forming a patterned mask over the 2-D material channel layer, wherein the patterned mask comprises openings exposing source/drain regions of the 2-D material channel layer; performing a plasma treatment to the source/drain regions of the 2-D material channel layer through the openings of the patterned mask, wherein chalcogen atoms of the source/drain regions of the 2-D material channel layer are replaced with reactive gas atoms of the plasma treatment; and after the plasma treatment is complete, forming source/drain electrodes in the openings of the patterned mask.

### PRIORITY CLAIM AND CROSS-REFERENCE

This application claims priority to U.S. Provisional Application Serial Number 63/801,366, filed May 07, 2025, which are herein incorporated by references in their entireties.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E illustrate a semiconductor device in various stages of fabrication in accordance with some embodiments.

FIG. 2 is a schematic view of a monolayer of an example TMD in accordance with some example embodiments.

FIGS. 3A and 3B are schematic views of a monolayer of an example TMD in accordance with some example embodiments.

FIG. 4 is a schematic diagram of a deposition system in accordance with some embodiments of the present disclosure.

FIGS. 5A, 5B, and 5C show experiment results of a 2-D material layer in accordance with some embodiments.

FIGS. 6A, 6B, and 6C show experiment results of a 2-D material layer in accordance with some embodiments.

FIGS. 7A and 7B show band structures of 2-D material layers in accordance with some embodiments.

FIG. 8 show experiment results of a semiconductor device in accordance with some embodiments.

FIG. 9 is a schematic view of a semiconductor device in accordance with some example embodiments.

FIGS. 10A-10B illustrate a semiconductor device in various stages of fabrication in accordance with some embodiments.

FIG. 11 is a schematic view of a monolayer of an example TMD in accordance with some example embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

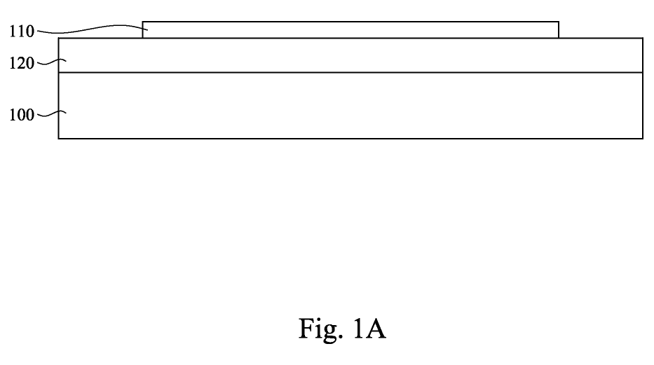

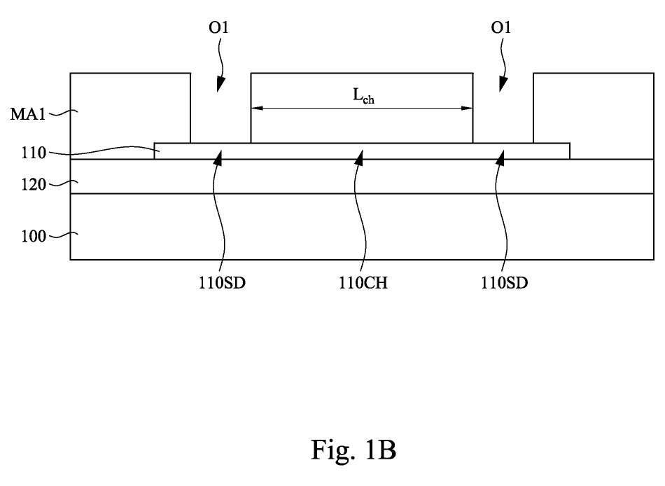

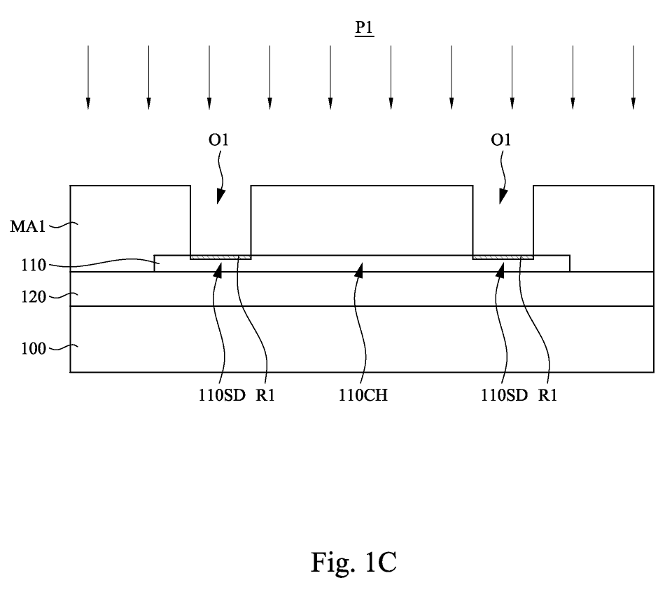

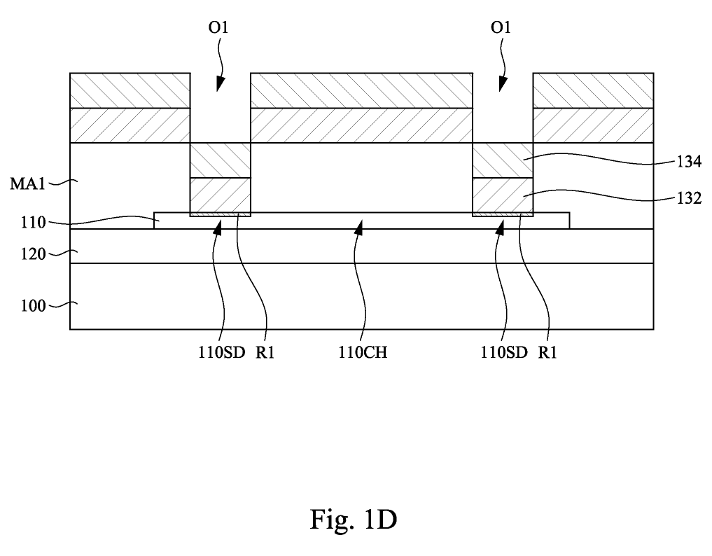

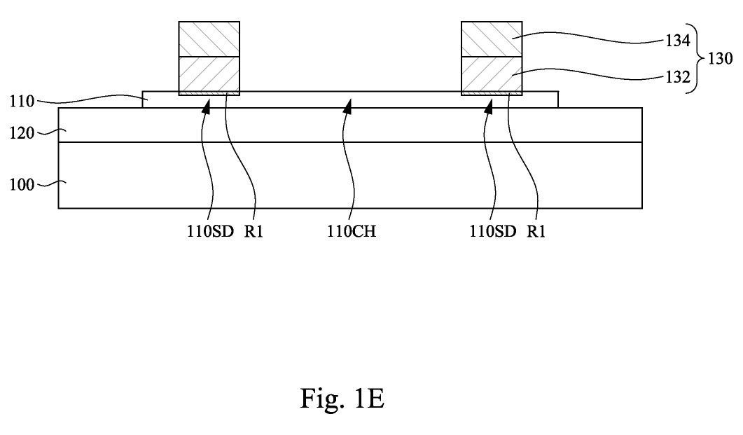

Reference is made to FIG. 1A. Shown there is a substrate 100. In some embodiments, the substrate 100 may be a conductive substrate, such as polysilicon substrate. The substrate 100 may be doped with a p-type dopant, such as boron, aluminum, gallium, or the like. For example, the substrate 100 may be made of p-doped polysilicon.

A dielectric layer 120 is formed over the substrate 100. In some embodiments, the dielectric layer 120 may include silicon nitride (e.g., Si₃N₄), silicon dioxide (e.g., SiO₂), aluminum oxide (Al₂O₃), hafnium oxide (HfO₂), while in other embodiments the dielectric layer 120 may be a high-k dielectric. In some embodiments, the substrate 100 may serve as a gate electrode of a transistor and the dielectric layer 120 may act a gate dielectric layer of a transistor. Accordingly, the substrate 100 can also be referred to as a gate electrode, and the dielectric layer 120 can also be referred to as a gate dielectric layer. In some embodiments, the dielectric layer 120 and the substrate 100 can be collectively referred to as a gate structure.

In other embodiments where the substrate 100 does not function as a gate electrode, the substrate 100 may include suitable material. The substrate 100 may be a semiconductor material such as silicon, germanium, diamond, or the like. Alternatively, compound materials such as silicon germanium, silicon carbide, silicon oxide, gallium arsenic, indium arsenide, indium phosphide, silicon germanium carbide, gallium arsenic phosphide, gallium indium phosphide, sapphire, combinations of these, and the like, with other crystal orientations, may also be used.

A 2-D material channel layer 110 is formed over the dielectric layer 120. In some embodiments, the 2-D material channel layer 110 may be mechanically transferred and placed over the dielectric layer 120, and the 2-D material channel layer 110 is adhered to the dielectric layer 120 through Van der Waals force. In some other embodiments, the 2-D material channel layer 110 may be formed on the dielectric layer 120 using chemical vapor deposition (CVD) process, atomic layer deposition (ALD) process, or other suitable processes.

After the 2-D material channel layer 110 is formed over the dielectric layer 120, an annealing process may be performed to increase the adhesion between the 2-D material channel layer 110 and the dielectric layer 120. In some embodiments, the annealing process may be performed under an argon (Ar) environment at a temperature in a range from about 150° C to about 200° C (e.g., 190° C) for about 30 min to about 60 min (e.g., 45 min).

As used herein, consistent with the accepted definition within solid state material art, a “2-D material” may refer to a crystalline material consisting of a single layer of atoms. As widely accepted in the art, “2-D material” may also be referred to as a “monolayer” material. In this content, “2-D material” and “monolayer” material are used interchangeably without differentiation in meanings, unless specifically pointed out otherwise. The 2-D material layer may be 2-D materials of suitable thickness. In some embodiments, a 2-D material includes a single layer of atoms in each of its monolayer structure, so the thickness of the 2-D material refers to a number of monolayers of the 2-D material, which can be one monolayer or more than one monolayer. The coupling between two adjacent monolayers of 2-D material includes van der Waals forces, which are weaker than the chemical bonds between/among atoms within the single monolayer. In some embodiments, the 2-D material channel layer 110 may be a single monolayer structure, or may also be a multi-layer structure, such as about 1 to 10 monolayers.

In some embodiments, the 2-D material channel layer 110 may be made of transition metal dichalcogenide (TMD). That is, the 2-D material channel layer 110 may be a metal-containing 2-D material layer. In some embodiment where the 2-D material channel layer 110 includes TMD monolayer, the TMD monolayer include tungsten diselenide (WSe₂), molybdenum disulfide (MoS₂), molybdenum diselenide (MoSe₂) molybdenum ditelluride (MoTe₂), tungsten disulfide (WS₂), tungsten ditelluride (WTe₂), or the like.

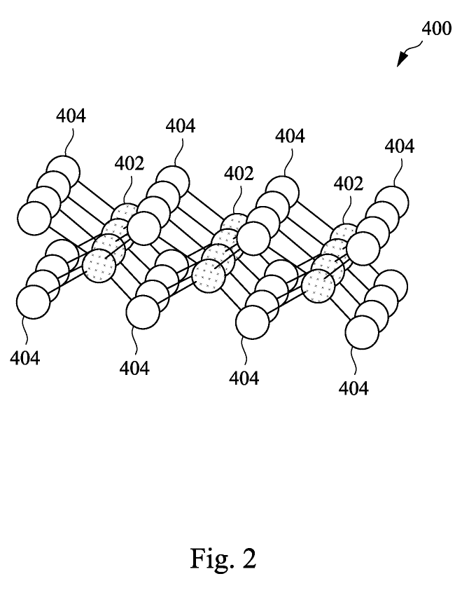

Reference is made to FIG. 2. FIG. 2 illustrates a schematic view of a monolayer 400 of an example TMD in accordance with some example embodiments. In FIG. 2, the one-molecule thick TMD material layer includes transition metal atoms 402 and chalcogen atoms 404. The transition metal atoms 402 may form a layer in a middle layer of the one-molecule thick TMD material layer, and the chalcogen atoms 404 may form an upper layer over the middle layer of transition metal atoms 402, and a lower layer underlying the middle layer of transition metal atoms 402. The transition metal atoms 402 may be tungsten (W) atoms or molybdenum (Mo) atoms, while the chalcogen atoms 404 may be sulfur (S) atoms, selenium (Se) atoms, or tellurium (Te) atoms. Throughout the description, the illustrated cross-bonded layers including one layer of transition metal atoms 402 and two layers of chalcogen atoms 404 in combination are referred to as a monolayer 400 of TMD.

Reference is made to FIG. 1B. A mask MA1 is formed over the substrate 100 and covering the 2-D material channel layer 110. The mask MA1 is then patterned to form openings O1 that expose top surfaces of source/drain regions 110SD of the 2-D material channel layer 110. On the other hand, the region of the 2-D material channel layer 110 between the source/drain regions 110SD can be referred to as channel region 110CH. In some embodiments, the channel length L_{ch} of the channel region 110CH of the 2-D material channel layer 110 is about 1 um to about 100 nm.

In some embodiments, the patterned mask MA1 may be a photoresist. For example, the substrate 100 is coated with a resist layer to be patterned in a lithography process using an electron-beam lithography system. The resist layer includes a resist material sensitive to electrons (so also referred to as e-beam resist). The resist material includes a component that resist to an IC fabrication process, such as etch and/or ion implantation. The resist material further includes a component sensitive to electrons. The resist material may be negative tone or positive tone. In some embodiments, the resist material includes polymethyl methacrylate (PMMA). In some embodiments, the resist material is patterned using helium (He) ion beam.

Reference is made to FIG. 1C. A plasma treatment P1 is performed to the source/drain regions 110SD of the 2-D material channel layer 110 through the openings O1 of the mask MA1. As a result, treated regions R1 are formed in the source/drain regions 110SD of the 2-D material channel layer 110. In some embodiments where the 2-D material channel layer 110 is made of TMD, the plasma treatment P1 is performed to replace parts of the chalcogen atoms of the 2-D material channel layer 110 with the atoms of the reactive gas used in the plasma treatment P1. For example, the plasma treatment P1 may include pure nitrogen (N₂) plasma, and the plasma treatment P1 is performed to replace parts of the chalcogen atoms of the 2-D material channel layer 110 with nitrogen (N) atoms. Here, the term “pure nitrogen (N₂) plasma” indicates that only nitrogen (N₂) gas is used in the plasma treatment P1. In other embodiments, the reactive gas of the plasma treatment P1 may also include H₂, Ar, N₂, SF₆, Cl₂, etc.

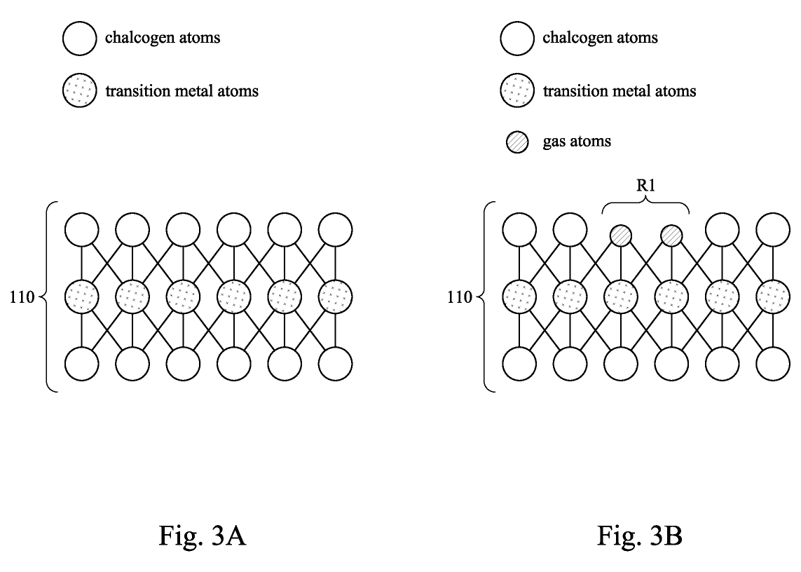

More specifically, as shown in FIGS. 3A and 3B, in which FIG. 3A is a schematic view of the 2-D material channel layer 110 prior to performing the plasma treatment P1, and FIG. 3B is a schematic view of the 2-D material channel layer 110 after performing the plasma treatment P1. As shown in FIG. 3A, when the 2-D material channel layer 110 is a single monolayer, the 2-D material channel layer 110 includes a lower layer of chalcogen atoms, an upper layer of chalcogen atoms, and a middle layer of transition metal atoms sandwiched between the lower layer and the upper layer of chalcogen atoms.

As shown in FIG. 3B, during the plasma treatment P1, the exposed region of the 2-D material channel layer 110 may be subject to the plasma treatment P1, and covalent bonds between the chalcogen atoms and the transition metal atoms may be broken through the plasma. On the other hand, the reactive gas atoms of the plasma treatment P1 may form covalent bonds with the free transition metal atoms. Here, the exposed region of the 2-D material channel layer 110 may be the top surfaces of the source/drain regions 110SD of the 2-D material channel layer 110 that are exposed through the openings O1 of the mask MA1 as shown in FIG. 1C. In some embodiments, the 2-D material channel layer 110 may be made of WSe₂, and the plasma treatment P1 may include nitrogen (N₂) plasma, parts of the Se atoms of the WSe₂layer are replaced with N atoms, and W-N covalent bonds are formed.

Moreover, because the top surface of the source/drain regions 110SD of the 2-D material channel layer 110 are exposed through the openings O1, and bottom surfaces of the source/drain regions 110SD of the 2-D material channel layer 110 remain covered by the dielectric layer 120 during the plasma treatment P1, only the exposed chalcogen atoms at the upper layer of the source/drain regions 110SD of the 2-D material channel layer 110 are replaced with the reactive gas atoms of the plasma treatment P1 (see FIG. 3B). That is, the chalcogen atoms at the lower layer of the 2-D material channel layer 110 are not replaced with the gas atoms once the plasma treatment P1 is complete. Moreover, the transition metal atoms of the 2-D material channel layer 110 are not removed during the plasma treatment P1.

Accordingly, as shown in FIG. 1C, the treated regions R1 may be present at the top portions of the source/drain regions 110SD of the 2-D material channel layer 110, while the bottom portions of the source/drain regions 110SD remain un-treated. It is noted that other portions of the 2-D material channel layer 110 aside from the treated regions R1 can be referred to as un-treated regions.

In some embodiments, the treated regions R1 can also be referred to as doped regions where the doping species is the reactive gas atoms of the plasma treatment P1. The doping species is different from the chalcogen atoms and the transition metal atoms of the 2-D material channel layer 110. The atomic concentration of the doping species is higher in the treated regions R1 than in other regions of the 2-D material channel layer 110. In some embodiments where the reactive atoms are nitrogen (N) atoms, the treated regions R1 can also be referred to as nitrogen-containing regions.

In some embodiments, the channel region 110CH of the 2-D material channel layer 110 are protected by the mask MA1 and the dielectric layer 120, and thus the chalcogen atoms within the channel region 110CH of the 2-D material channel layer 110 are not replaced with the reactive gas atoms of the plasma treatment P1. That is, the channel region 110CH of the 2-D material channel layer 110 may be free of the reactive gas atoms of the plasma treatment P1.

In some embodiments, the plasma treatment P1 is performed under a temperature less than 400° C. In other embodiments, the plasma treatment P1 is performed under a temperature less than 100° C. For example, the temperature of the plasma treatment P1 is in a range from about 50° C to about 400° C. If the temperature is too high (e.g., much greater than 400° C), the plasma may be too strong, and the source/drain region 110SD of the 2-D material channel layer 110 may be damaged. If the temperature is too low (e.g., much lower than 50° C), the plasma may not be strong enough to break the covalent bonds between the chalcogen atoms and the transition metal atoms.

In some embodiments, the plasma treatment P1 is performed under a power in a range from about 20W to about 100W, such as about 25W. If the power is too high (e.g., much greater than 100W), the plasma may be too strong, and the source/drain region 110SD of the 2-D material channel layer 110 may be damaged. If the temperature is too low (e.g., much lower than 20W), the plasma may not be strong enough to break the covalent bonds between the chalcogen atoms and the transition metal atoms.

In some embodiments, the plasma treatment P1 is performed for a duration in a range from about 60s to about 90s. If the duration is too long (e.g., much greater than 90s), the plasma may be too strong, and the source/drain region 110SD of the 2-D material channel layer 110 may be damaged. If the duration is too short (e.g., much shorter than 60s), the plasma may not be strong enough to break the covalent bonds between the chalcogen atoms and the transition metal atoms.

In some embodiments, the flow rate(s) of the reactive gas(es) are in a range from about 2 sccm to about 50 sccm, such as about 10 sccm. If the flow rate is too high (e.g., much greater than 50 sccm), the plasma may be too strong, and the source/drain region 110SD of the 2-D material channel layer 110 may be damaged. If the flow rate is too low (e.g., much lower than 2 sccm), the plasma may not be strong enough to break the covalent bonds between the chalcogen atoms and the transition metal atoms.

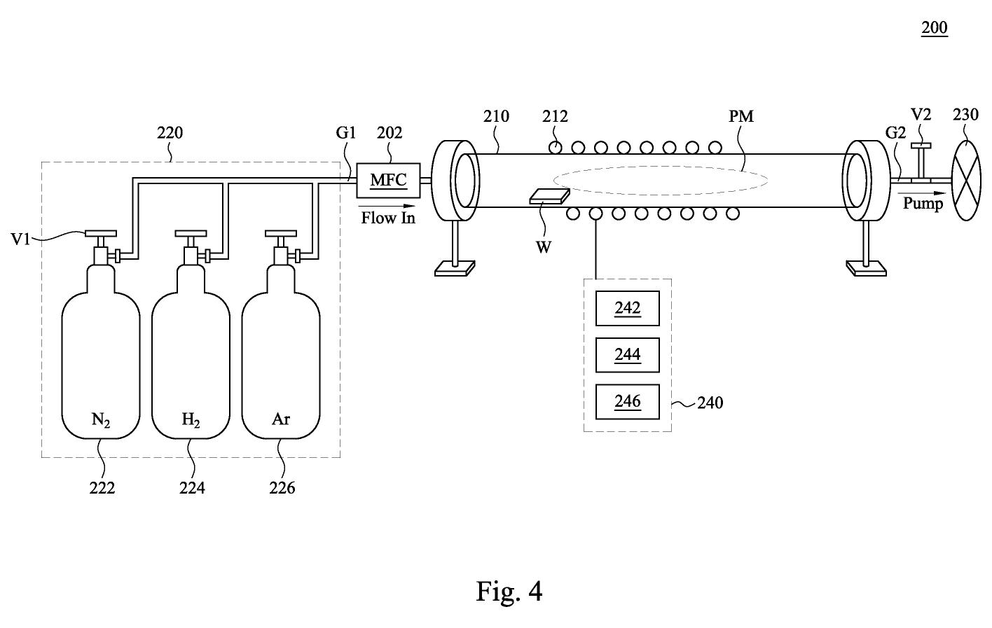

Reference is made to FIG. 4. FIG. 4 illustrates an exemplary plasma system 200 for performing the plasma treatment P1 of FIG. 1C. In some embodiments, the plasma system 200 is an inductively coupled plasma (ICP) system. The ICP system of FIG. 4 includes a processing chamber 210, a gas delivery system 220, a pumping system 230, and an RF system 240. In some embodiments, the gas delivery system 220 is connected to the processing chamber 210 via a gas delivery line G1, and the pumping system 230 is connected to the processing chamber 210 via a gas delivery line G2. The RF system 240 is coupled to the processing chamber 210 by a coil 212 wound around the exterior of the processing chamber 210.

The gas delivery system 220 will now be described. In some embodiments, the gas delivery system 220 includes several sources 222, 224, and 226. In the example shown in FIG. 4, three sources are illustrated, while more or less sources may be applied in some other embodiments. In some embodiments, each of the sources 222, 224, and 226 is configured with a valve V1. Moreover, a mass flow controller (MFC) 202 is arranged along a gas delivery path between the gas delivery system 220 and the processing chamber 210, so as to control the flow rates of the gasses delivered to the processing chamber 210. In some embodiments, the gas sources 222, 224, and 226 may include gas cylinders. The gases of the sources 222, 224, and 226 may be, for example, nitrogen (N₂), hydrogen (H₂), and argon (Ar), respectively.

The pumping system 230 will now be described. In some embodiments, the pumping system 230 includes a vacuum pump. The pumping system 230 is connected to the gas delivery line G2 via a valve V2. The remainder of the gas mixture exhausted from the processing chamber 210, including reaction products or byproducts, is evacuated from the processing chamber 210 by the vacuum pump.

The RF system 240 will now be described. The RF system 240 includes an RF source 242, a matching box 244, and a controller 246. In some embodiments, the RF energy is supplied to the processing chamber 210 by the inductive coil 212 which is powered by the RF source 242 and the matching box 244. The input of the matching box 244 is coupled to the RF source 242, which provides RF power for plasma generation. The matching box 244 is used to match the impedance of the coil 212 to the impedance of the RF source 242, in order to deliver the maximum power to the plasma in the processing chamber 210. In some embodiments, the matching box 244 includes a matching network, a Phase and Magnitude Detector (PMD) and a controller that automatically tunes the matching network using the information supplied by the PMD. The controller 246 may control the operation of the RF source 242. The controller 246 may include, for example, a computer including a central processing unit (CPU), a memory, and support circuits. The controller 246 operates under the control of a computer program stored in the memory or through other computer programs, such as programs stored in a removable memory. The computer program dictates, for example, the timing, mixture of gases, RF power levels and other parameters of a particular process.

In some embodiments, the inductive coil 212 is connected to the RF system 240 through a transmission line such as a wave guide or a co-axial cable. The coil 212 may be made of copper (Cu), or other suitable conductive materials. In some embodiments, the coil 212 has a multiple turn cylindrical configuration and may have an electrical length of about one-quarter wavelength (<λ/4) at the operating frequency. For example, the coil 212 is positioned outside the processing chamber 210 for coupling the RF magnetic fields into the processing chamber 210. These induced RF magnetic fields ionize at least part of the process gases and thus form plasma in processing chamber 210.

In some embodiments, when the plasma treatment P1 of FIG. 1C is going to be performed, a wafer W, which includes the structure shown in FIG. 1C, is transferred to the processing chamber 210. Reactive gas is delivered from the gas delivery system 220 to the processing chamber 210 through the gas delivery line G1. Then, an RF power is turned on to generate a plasma PM in the processing chamber 210. Once the plasma treatment P1 of FIG. 1C is complete, the gas in the processing chamber 210 may be pumped away to the gas delivery line G2 through the pumping system 230.

As shown in FIG. 4, when the plasma PM is generated, the plasma PM may include an elliptical profile. In some embodiments, the wafer W is placed laterally offset from the center of the plasma PM, which will reduce the intensity of the plasma PM applied to the wafer W. Accordingly, the plasma treatment P1 is able to replace only the chalcogen atoms of the 2-D material channel layer 110 with the reactive gas atoms without damaging the 2-D material channel layer 110. If the wafer W is placed at the center of the plasma PM, the plasma intensity may be too strong, and the 2-D material channel layer 110 (see FIG. 1C) may be severely damaged by the plasma PM. For example, the transition metal atoms at the source/drain regions 110SD of the 2-D material channel layer 110 may be unwantedly removed during the plasma treatment P1. In some embodiments, the edge of the plasma PM may cover a portion of the top surface of the wafer W (e.g., the substrate 100 of FIG. 1C), while another portion of the top surface of the wafer W may be free of coverage by the plasma PM.

It is noted that the plasma treatment P1 as discussed in FIG. 1C may also be beneficial to remove photoresist residues. For example, after the openings O1 are formed as shown in FIG. 1B, photoresist residues (not shown) may present on top surfaces of the source/drain regions 110SD of the 2-D material channel layer 110, and the plasma treatment P1 can remove the photoresist residues to clean the exposed surfaces of the source/drain regions 110SD of the 2-D material channel layer 110.

Reference is made to FIG. 1D. After the plasma treatment P1 is complete, a first conductive layer 132 and a second conductive layer 134 are sequentially deposited in the openings O1 of the mask MA1 and over the top surface of the mask MA1. In some embodiments, the first conductive layer 132 and the second conductive layer 134 may be deposited using suitable deposition process, such as physical vapor deposition (PVD), evaporation, chemical vapor deposition (CVD) process, atomic layer deposition (ALD) process, or other suitable processes. In some embodiments, the first conductive layer 132 and the second conductive layer 134 may include different conductive materials or different metals. For example, the first conductive layer 132 and the second conductive layer 134 may include antimony (Sb) and platinum (Pt), respectively. In some embodiments, the first conductive layer 132 has a thickness about 10 nm and the second conductive layer 132 has a thickness about 12 nm. In some embodiments, the first conductive layer 132 and the second conductive layer 134 can be deposited in the same chamber as performing the plasma treatment P1 of FIG. 1C. That is, the formation of the first conductive layer 132 and the second conductive layer 134 and the plasma treatment P1 can be in-situ performed.

Reference is made to FIG. 1E. The mask MA1 is removed, while leaving portions of the first conductive layer 132 and the second conductive layer 134 in the openings O1 of the mask MA1 remain over the 2-D material channel layer 110. In some embodiments, the mask MA1 can be removed using a stripping process. In some embodiments, portions of the first conductive layer 132 and the second conductive layer 134 over the top surface of the mask MA1 are removed together with the mask MA1. In some embodiments, the remaining portions of the first conductive layer 132 and the second conductive layer 134 can be referred to as source/drain electrodes 130, in which the source/drain electrodes 130 are disposed over the source/drain regions 110SD of the 2-D material channel layer 110, respectively.

As mentioned above, because the source/drain regions 110SD of the 2-D material channel layer 110 undergo the plasma treatment P1 as discussed in FIG. 1C, parts of the chalcogen atoms of the source/drain regions 110SD of the 2-D material channel layer 110 are replaced with the reactive gas atoms of the plasma treatment P1. Accordingly, the reactive gas atoms of the plasma treatment P1 may be present between the first conductive layer 132 of the source/drain electrodes 130. In some embodiments, the chalcogen atoms may not present between the transition metal atoms of the source/drain regions 110SD of the 2-D material channel layer 110 and the first conductive layer 132 of the source/drain electrodes 130.

Once the source/drain electrodes 130 are formed, a semiconductor device, such as a transistor, is formed. For example, the substrate 100 and the dielectric layer 120 may serve as the gate structure of the semiconductor device, in which the substrate 100 may serve as the gate electrode and the dielectric layer 120 may serve as the gate dielectric, respectively. The 2-D material channel layer 110 may serve as the channel layer of the semiconductor device. In some embodiments, the structure of FIG. 1E can also be referred to as a back-gate semiconductor device. It is noted that the dielectric layer 120 and the substrate 100 are not affected by the plasma treatment P1 as discussed in FIG. 1C. Accordingly, the plasma treatment P1 would not cause leakage or gate control issue in the device in FIG. 1E.

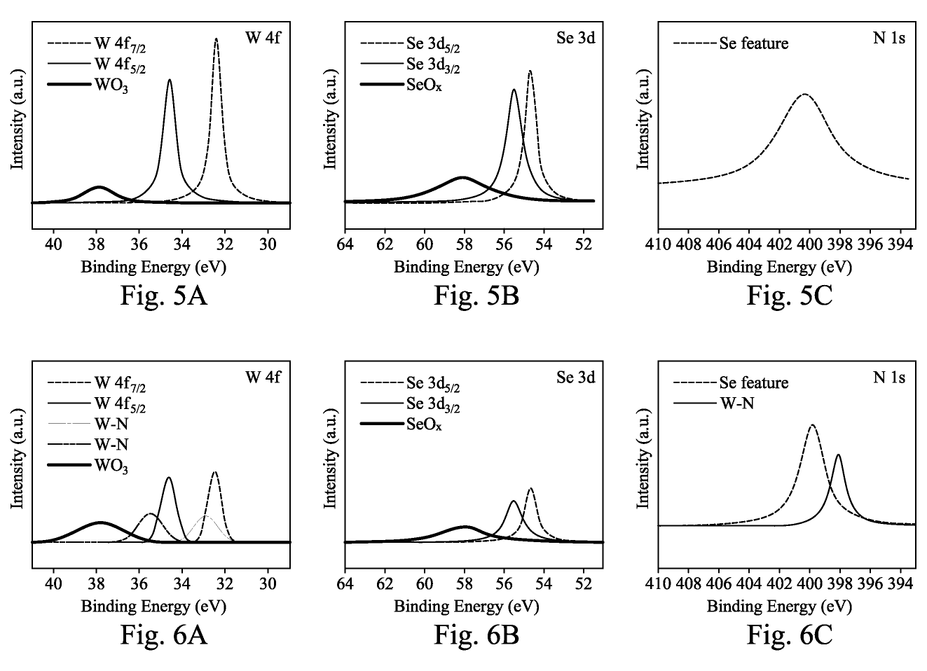

FIGS. 5A, 5B, and 5C show experiment results of a 2-D material layer in accordance with some embodiments. FIGS. 6A, 6B, and 6C show experiment results of a 2-D material layer in accordance with some embodiments. In greater detail, FIGS. 5A to 5C are experiment results of a 2-D material layer (e.g., the 2-D material channel layer 110) without performing the plasma treatment P1 as discussed above. On the other hand, FIGS. 6A to 6C are experiment results of a 2-D material layer where the plasma treatment P1 is performed. It is noted that in the experiments of FIGS. 5A to 5C and 6A to 6C, the 2-D material layer is WSe₂, and the plasma treatment P1 is nitrogen (N₂) plasma.

Comparing FIGS. 5A and 6A, it can be seen that the peaks of W-N bonding signal are observed in the sample where N₂ plasma is performed. Comparing FIGS. 5B and 6B, it can be seen that peaks of Se signal decrease in the sample where N₂ plasma is performed. Comparing FIGS. 5C and 6C, it can be seen that the peak of W-N bonding signal is observed in the sample where N₂ plasma is performed. The results demonstrate that when N₂ plasma is applied to a WSe₂2-D material layer, parts of the Se atoms are replaced with N₂atoms. Accordingly, the Se atomic concentration in the 2-D material layer is reduced as a result of the N₂plasma.

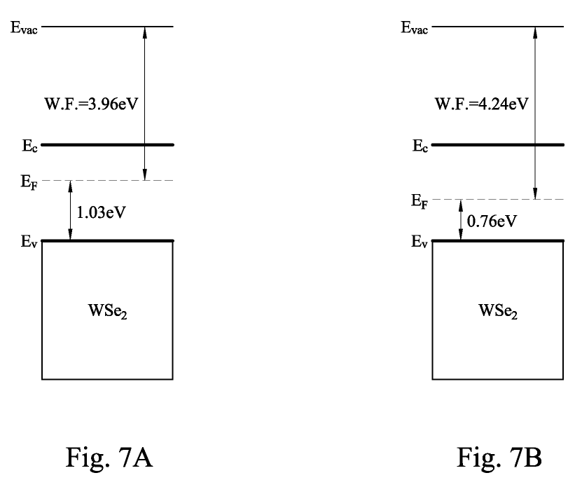

FIGS. 7A and 7B show band structures of 2-D material layers in accordance with some embodiments. In greater detail, FIG. 7A is a band structure of a 2-D material layer (e.g., the 2-D material channel layer 110) without performing the plasma treatment P1 as discussed above. On the other hand, FIG. 7B is a band structure of a 2-D material layer where the plasma treatment P1 is performed. It is noted that the 2-D material layer is WSe₂, and the plasma treatment P1 is nitrogen (N₂) plasma. In FIGS. 7A and 7B, E_{V} denotes valence band energy, E_{F} denotes Fermi level, E_{c} denotes conduction band, and E_{vac} denotes vacuum energy level. The band structures of FIGS. 7A and 7B can be obtained through ultraviolet photoelectron spectroscopy (UPS) analysis.

Comparing FIGS. 7A and 7B, it can be seen that the work function value of the 2-D material layer increases from 3.96 eV to 4.24 eV after the plasma treatment P1 is performed. The work function value is calculated as the difference between the vacuum level E_{vac} and the Fermi level E_{F}. On the other hand, the fermi level E_{F} the 2-D material layer decreases after the plasma treatment P1 is performed. For example, when the plasma treatment P1 is absent, the energy difference between the Fermi level E_{F} and the valence band E_{V} is 1.03 eV. On the other hand, when the plasma treatment P1 is performed, the energy difference between the Fermi level E_{F} and the valence band E_{V} is 0.76 eV. The increasing work function value and the regulated Fermi level demonstrate that the property of the 2-D material layer has been changed through the plasma treatment P1.

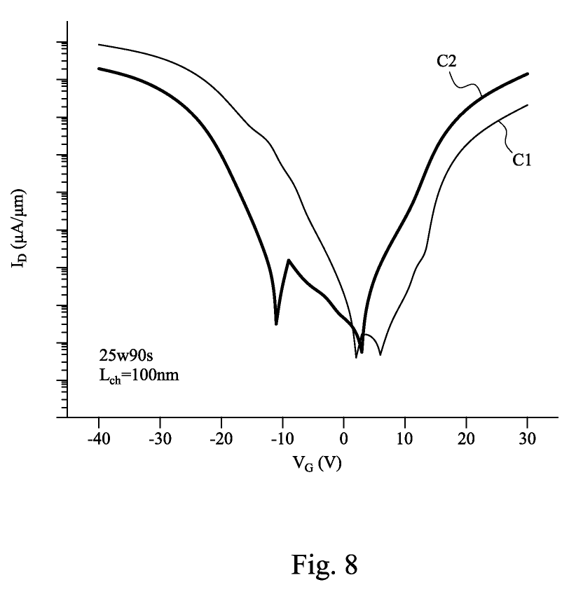

FIG. 8 show experiment results of a semiconductor device in accordance with some embodiments. In greater detail, FIG. 8 show an I-V curve C1 of a semiconductor device where the plasma treatment P1 is performed and an I-V curve C2 of a semiconductor device where no plasma treatment is performed. It is noted that the 2-D material layer is WSe₂, and the plasma treatment P1 is nitrogen (N₂) plasma. Moreover, the plasma treatment P1 is performed at a power of 25W for 90s, and the channel length L_{CH} is 100 nm. It is noted that in FIG. 8, the lateral axis denotes gate voltage V_{G} and the horizontal axis denotes drain current I_{D}.

Comparing the I-V curves C1 and C2, it can be seen that the p-current increases from 19.9 uA/um to 55.5 uA/um when the plasma treatment P1 is performed (see drain current at V_{G} = -40V). The threshold voltage VT of the device increase from -27.2V to -21.3V when the plasma treatment P1 is performed. The On/Off ratio of the device increases from 3.7 x 10⁷ to 2.1 x 10⁸ when the plasma treatment P1 is performed. The carrier mobility of the device increases from 2.34 cm²/(V*s) to 6.4 cm²/(V*s) when the plasma treatment P1 is performed. The contact resistance between the source/drain electrode (e.g., source/drain electrode 130) and the 2-D material layer (e.g., 2-D material channel layer 110) reduced from 1.98 kΩ*um to 1.0 kΩ*um when the plasma treatment P1 is performed. The results show that when the plasma treatment P1 is performed, the performance of the device is improved, and the device characteristics change from bipolar to N/P-FET characteristics, which is more conducive to the future process. In some embodiments where the 2-D material channel layer 110 is made of WSe2 and the plasma treatment P1 is N₂plasma, the semiconductor device of FIG. 1E may be p-type transistor.

Moreover, in an Atomic Force Microscope (AFM) analysis, the surface roughness of semiconductor device with the plasma treatment P1 and the surface roughness of semiconductor device without the plasma treatment P1 are measured. In the AFM results, the surface roughness of the 2-D material layer (e.g., WSe₂) without the plasma treatment P1 is 0.856 nm, and the surface roughness of the 2-D material layer (e.g., WSe₂) with the plasma treatment P1 is 0.824 nm. This demonstrates that the surface roughness of the 2-D material layer does not significantly change after performing the plasma treatment P1, which indicates that the 2-D material layer is not severely damaged during the plasma treatment P1. On the other hand, in a transmission electron microscopy (TEM) analysis, the structure of semiconductor device with the plasma treatment P1 is measured. In the TEM result, the 2-D material layer (e.g., WSe₂) is not damaged by the plasma treatment P1 and the contact surface between the 2-D material layer and the source/drain contact is not affected.

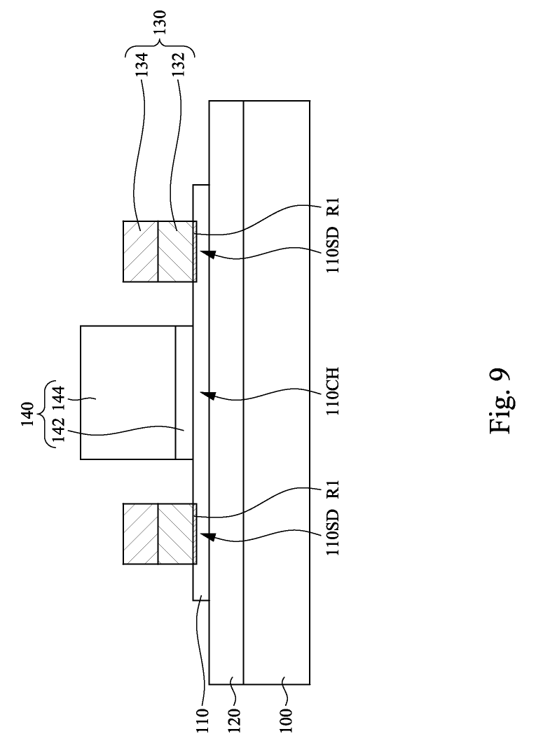

FIG. 9 is a schematic view of a semiconductor device in accordance with some example embodiments. It is noted that some elements in FIG. 9 are similar to those discussed in FIGS. 1A to 1E, such elements will be labeled the same, and relevant details will not be repeated for brevity.

FIG. 9 is different from FIG. 1E, in that FIG. 9 illustrates a front-gate semiconductor device where a gate structure 140 is formed on the top surface of the channel region 110CH of the 2-D material channel layer 110. In some embodiments, the gate structure 140 includes a gate dielectric layer 142 and a gate electrode 144 over the gate dielectric layer 142.

In some embodiments, the gate dielectric layer 142 may include a dielectric material such as SiO₂, HfSiO, or SiON. In some embodiments, the gate dielectric layer 142 may include a high-k dielectric layer, or in some cases may include a high-K layer formed over an interfacial layer. High-k dielectrics, as used and described herein, include dielectric materials having a high dielectric constant, for example, greater than that of thermal silicon oxide (˜3.9). In some embodiments, the gate electrode 144 may include a conductive layer such as W, TiN, TaN, WN, Re, Ir, Ru, Mo, Al, Cu, Co, Ni, Cr, Ti, Au, Pd, Ag, Pt, Fe, combinations thereof, and/or other suitable compositions. In some embodiments, the gate electrode l44 may include a polysilicon layer.

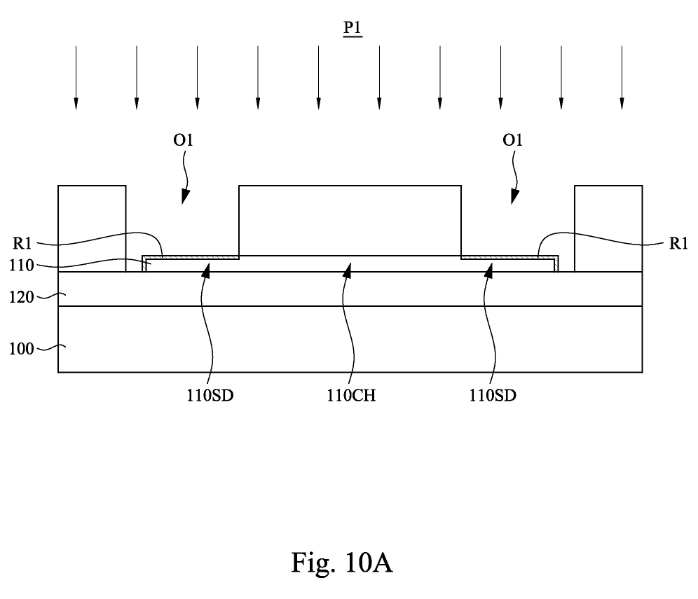

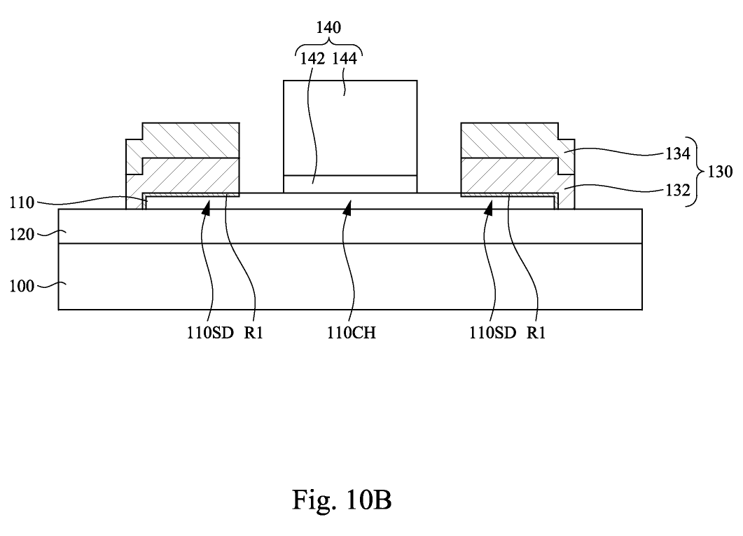

FIGS. 10A to 10B illustrate a semiconductor device in various stages of fabrication in accordance with some embodiments. It is noted that some elements in FIGS. 10A to 10B are similar to those discussed in FIGS. 1A to 1E, such elements will be labeled the same, and thus relevant details will not be repeated for brevity.

Reference is made to FIG. 10A. FIG. 10A is similar to FIG. 1C where a plasma treatment P1 is performed to the source/drain regions 110SD of the 2-D material channel layer 110. The difference between FIG. 10A and FIG. 1C is that the openings O1 may expose edges (or sidewalls) of the source/drain regions 110SD of the 2-D material channel layer 110 and top surface of the dielectric layer 120. Accordingly the treated regions R1 may extend from the top surfaces of the source/drain regions 110SD of the 2-D material channel layer 110 to edges (or sidewalls) of the source/drain regions 110SD of the 2-D material channel layer 110.

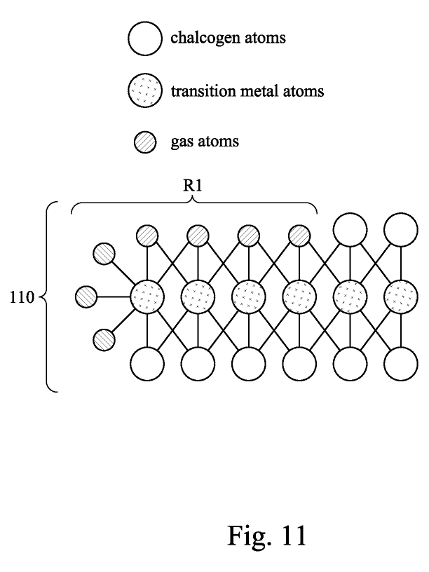

As shown in FIG. 11, because the top surface of the source/drain regions 110SD of the 2-D material channel layer 110 and the edges of the source/drain regions 110SD of the 2-D material channel layer 110 are exposed through the openings O1, and bottom surface of the source/drain regions 110SD of the 2-D material channel layer 110 remain covered by the dielectric layer 120 during the plasma treatment P1, only the exposed chalcogen atoms at the upper layer of the source/drain regions 110SD of the 2-D material channel layer 110 are replaced with the reactive gas atoms of the plasma treatment P1. That is, the chalcogen atoms at the lower layer of the 2-D material channel layer 110 are not replaced with the gas atoms once the plasma treatment P1 is complete. Moreover, the reactive gas atoms of the plasma treatment P1 may also form covalent bonds with the transition metal atoms of the 2-D material channel layer 110 at the edge of the 2-D material channel layer 110. That is, the reactive gas atoms may be present laterally adjacent to the middle layer of the transition metal atoms of the 2-D material channel layer 110.

Reference is made to FIG. 10B. Source/drain electrodes 130 are formed over the source/drain regions 110SD of the 2-D material channel layer 110. The source/drain electrodes 130 may be formed through the processes as discussed in FIGS. 1D and 1E. Moreover, gate structure 140 is formed over the channel region 110CH of the 2-D material channel layer 110. In some embodiments, the gate structure 140 may also be omitted.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments provide a method for forming a 2-D material semiconductor device, in which a plasma treatment is performed to source/drain regions of 2-D material channel layer to modify the properties of the semiconductor device. With such configuration, the electrical performance the semiconductor device transistor is improved. Moreover, the device characteristics change from bipolar to N/P-FET characteristics, which is more conducive to the future CFET process.

In some embodiments of the present disclosure, a method includes forming a 2-D material channel layer over a substrate, wherein the 2-D material channel layer is made of transition metal dichalcogenide (TMD); forming a patterned mask over the 2-D material channel layer, wherein the patterned mask comprises openings exposing source/drain regions of the 2-D material channel layer; performing a plasma treatment to the source/drain regions of the 2-D material channel layer through the openings of the patterned mask, wherein chalcogen atoms of the source/drain regions of the 2-D material channel layer are replaced with reactive gas atoms of the plasma treatment; and after the plasma treatment is complete, forming source/drain electrodes in the openings of the patterned mask.

In some embodiments, the 2-D material channel layer comprises an upper layer of the chalcogen atoms, a lower layer of the chalcogen atoms, and a middle layer of transition metal atoms between the upper layer and the lower layer, and wherein the plasma treatment is performed to replace the chalcogen atoms at the upper layer with the reactive gas atoms of the plasma treatment.

In some embodiments, the chalcogen atoms at the lower layer are not replaced with the reactive gas atoms of the plasma treatment.

In some embodiments, the transition metal atoms are not removed during the plasma treatment.

In some embodiments, the reactive gas atoms of the plasma treatment form covalent bonds with transition metal atoms of the source/drain regions of the 2-D material channel layer.

In some embodiments, the plasma treatment is performed such that a work function value of the 2-D material layer changes.

In some embodiments, the method further includes forming a dielectric layer over the substrate prior to forming the 2-D material channel layer.

In some embodiments of the present disclosure, a method includes forming a 2-D material channel layer over a substrate, wherein the 2-D material channel layer is made of tungsten diselenide (WSe₂); performing a nitrogen (N₂) plasma treatment to source/drain regions of the 2-D material channel layer to form nitrogen-containing regions in the source/drain regions of the 2-D material channel layer; and after the N₂ plasma treatment is complete, forming source/drain electrodes over the source/drain regions of the 2-D material channel layer.

In some embodiments, the N₂ plasma treatment is performed for a duration in a range from about 60 s to about 90 s.

In some embodiments, the N₂ plasma treatment is performed under a temperature less than 400° C.

In some embodiments, the N₂ plasma treatment is performed under a power in a range from about 20 W to about 100 W.

In some embodiments, the N₂ plasma treatment is a pure N₂ plasma treatment.

In some embodiments, a nitrogen atomic concentration is higher at upper portions of the source/drain regions of the 2-D material channel layer than at lower portions of the source/drain regions of the 2-D material channel layer.

In some embodiments, the N₂plasma treatment is performed to replace selenium (Se) atoms of the source/drain regions of the 2-D material channel layer with nitrogen (N) atoms.

In some embodiments, a channel region of the 2-D material channel layer between the source/drain regions of the 2-D material is free of nitrogen (N) atoms.

In some embodiments of the present disclosure, a semiconductor device includes a substrate. A dielectric layer is over the substrate. A 2-D material channel layer made of transition metal dichalcogenide (TMD) is over the dielectric layer, the 2-D material channel layer comprising a channel region and source/drain regions on opposite sides of the channel region, wherein the source/drain regions of the 2-D material channel layer are different than the channel region of the 2-D material layer at least in nitrogen atomic concentration. Source/drain electrodes are over the source/drain regions of the 2-D material channel layer.

In some embodiments, upper portions of the source/drain regions of the 2-D material channel layer is different than lower portions of the source/drain regions of the 2-D material channel layer at least in nitrogen atomic concentration

In some embodiments, the channel region of the 2-D material channel layer is free of nitrogen.

In some embodiments, the 2-D material channel layer is a single monolayer.

In some embodiments, a covalent bond of nitrogen and transition metal atom of the 2-D material channel layer is present at the source/drain regions of the 2-D material channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a 2-D material channel layer over a substrate, wherein the 2-D material channel layer is made of transition metal dichalcogenide (TMD);
forming a patterned mask over the 2-D material channel layer, wherein the patterned mask comprises openings exposing source/drain regions of the 2-D material channel layer;
performing a plasma treatment to the source/drain regions of the 2-D material channel layer through the openings of the patterned mask, wherein chalcogen atoms of the source/drain regions of the 2-D material channel layer are replaced with reactive gas atoms of the plasma treatment; and
after the plasma treatment is complete, forming source/drain electrodes in the openings of the patterned mask.

2. The method of claim 1, wherein the 2-D material channel layer comprises an upper layer of the chalcogen atoms, a lower layer of the chalcogen atoms, and a middle layer of transition metal atoms between the upper layer and the lower layer, and wherein the plasma treatment is performed to replace the chalcogen atoms at the upper layer with the reactive gas atoms of the plasma treatment.

3. The method of claim 2, wherein the chalcogen atoms at the lower layer are not replaced with the reactive gas atoms of the plasma treatment.

4. The method of claim 2, wherein the transition metal atoms are not removed during the plasma treatment.

5. The method of claim 1, wherein the reactive gas atoms of the plasma treatment form covalent bonds with transition metal atoms of the source/drain regions of the 2-D material channel layer.

6. The method of claim 1, wherein the plasma treatment is performed such that a work function value of the 2-D material layer changes.

7. The method of claim 1, further comprising forming a dielectric layer over the substrate prior to forming the 2-D material channel layer.

8. A method, comprising:
forming a 2-D material channel layer over a substrate, wherein the 2-D material channel layer is made of tungsten diselenide (WSe₂);
performing a nitrogen (N₂) plasma treatment to source/drain regions of the 2-D material channel layer to form nitrogen-containing regions in the source/drain regions of the 2-D material channel layer; and
after the N₂ plasma treatment is complete, forming source/drain electrodes over the source/drain regions of the 2-D material channel layer.

9. The method of claim 8, wherein the N₂plasma treatment is performed for a duration in a range from about 60 s to about 90 s.

10. The method of claim 8, wherein the N₂ plasma treatment is performed under a temperature less than 400° C.

11. The method of claim 8, wherein the N₂ plasma treatment is performed under a power in a range from about 20 W to about 100W.

12. The method of claim 8, wherein the N₂ plasma treatment is a pure N₂ plasma treatment.

13. The method of claim 8, wherein a nitrogen atomic concentration is higher at upper portions of the source/drain regions of the 2-D material channel layer than at lower portions of the source/drain regions of the 2-D material channel layer.

14. The method of claim 8, wherein the N₂ plasma treatment is performed to replace selenium (Se) atoms of the source/drain regions of the 2-D material channel layer with nitrogen (N) atoms.

15. The method of claim 8, wherein a channel region of the 2-D material channel layer between the source/drain regions of the 2-D material is free of nitrogen (N) atoms.

16. A semiconductor device, comprising:
a substrate;
a dielectric layer over the substrate;
a 2-D material channel layer made of transition metal dichalcogenide (TMD) over the dielectric layer, the 2-D material channel layer comprising a channel region and source/drain regions on opposite sides of the channel region, wherein the source/drain regions of the 2-D material channel layer are different than the channel region of the 2-D material layer at least in nitrogen atomic concentration; and
source/drain electrodes over the source/drain regions of the 2-D material channel layer.

17. The semiconductor device of claim 16, wherein upper portions of the source/drain regions of the 2-D material channel layer is different than lower portions of the source/drain regions of the 2-D material channel layer at least in nitrogen atomic concentration.

18. The semiconductor device of claim 16, wherein the channel region of the 2-D material channel layer is free of nitrogen.

19. The semiconductor device of claim 16, wherein the 2-D material channel layer is a single monolayer.

20. The semiconductor device of claim 16, wherein a covalent bond of nitrogen and transition metal atom of the 2-D material channel layer is present at the source/drain regions of the 2-D material channel layer.
